(19) United States
(12) Patent Application Publication
(10) Pub. No.: US 2025/0056819 A1
(43) Pub. Date: Feb. 13, 2025

(54) CAPACITOR STRUCTURE AND METHODS OF FORMING THE SAME

(71) Applicant: TAIWAN SEMICONDUCTOR MANUFACTURING COMPANY, LTD., Hsinchu (TW)

(72) Inventors: Wei-Lun Chung, Changhua (TW); Chung-Lei Chen, Hsinchu (TW); Anhao Cheng, Taichung (TW); Chien-Wei Lee, Taichung (TW); Yen-Liang Lin, Tainan (TW); Ru-Shang Hsiao, Hsinchu (TW)

(21) Appl. No.: 18/402,035

(22) Filed: Jan. 2, 2024

Related U.S. Application Data
(60) Provisional application No. 63/609,045, filed on Dec. 12, 2023.
(60) Provisional application No. 63/532,234, filed on Aug. 11, 2023.

(51) Int. Cl. H01L 29/94; H01L 27/06

(52) U.S. Cl. CPC H01L 29/94; H01L 27/0629; H01L 28/60

(57) ABSTRACT

A capacitor structure and methods of forming the same are described. In some embodiments, the structure includes a first well region, a first semiconductor layer disposed over the first well region, a second semiconductor layer disposed on the first semiconductor layer, and a dielectric layer disposed on the second semiconductor layer. The dielectric layer has a top surface, a bottom surface, one or more protrusions extending towards the second semiconductor layer, and one or more openings in the top surface. The structure further includes a gate structure disposed on the dielectric layer.

### CROSS-REFERENCE TO RELATED APPLICATIONS

This application claims priority to U.S. Provisional Application Ser. No. 63/532,234 filed Aug. 11, 2023 and U.S. Provisional Application Ser. No. 63/609,045 filed Dec. 12, 2023, which are incorporated by reference in their entirety.

### BACKGROUND

Metal-oxide semiconductor (MOS) capacitors are widely used for I/O signal noise reduction. A MOS capacitor includes an implant region that functions as a bottom electrode. The implant region may include high concentration of dopants in order to enhance the electric capacity. However, high dopant concentration may cause the MOS capacitor to have leakage paths after thermal processes/treatments. Thus, an improved MOS capacitor is needed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1I illustrate cross-sectional side views of various stages of manufacturing a MOS capacitor structure, in accordance with some embodiments.

FIGS. 2, 3A, 3B, 4A-4D, 5A, and 5B illustrate cross-sectional side views of the MOS capacitor structure, in accordance with alternative embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure relates to a MOS capacitor structure that can be integrated in front-end-of-line (FEOL) with transistor devices. In some embodiments, the MOS capacitor structure is formed along with MOS field effect transistors (MOSFETs). The MOS capacitor structure includes one or more semiconductor layers formed by an epitaxial growth process between a dielectric layer and a well region. The one or more semiconductor layers formed by an epitaxial growth process can prevent or reduce diffusion of species into the well region, which in turn reduces current leakage. In some embodiments, the dielectric layer of the MOS capacitor structure has a serpentine profile, which increases the surface area of the dielectric layer. As a result, the capacitance of the dielectric layer is increased, which in torn increases the capacitance of the MOS capacitor formed from the MOS capacitor structure.

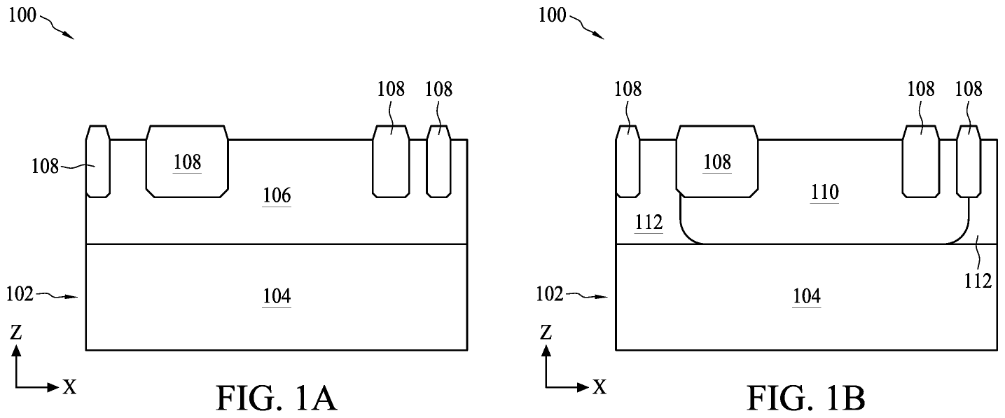

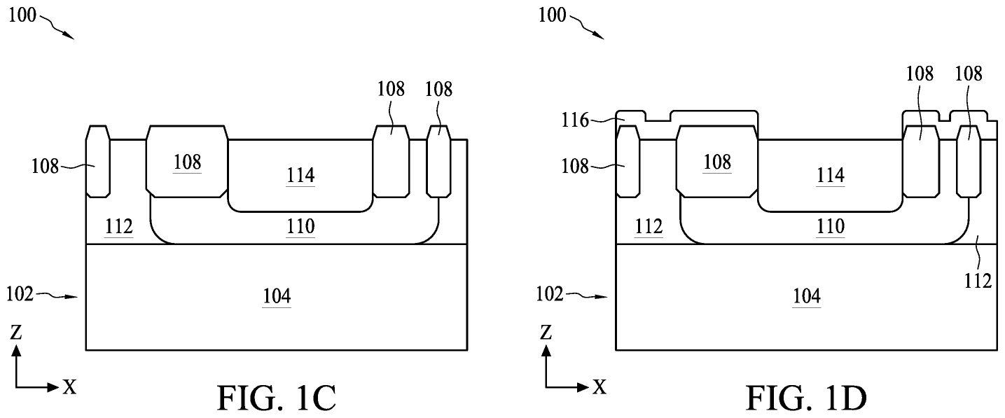

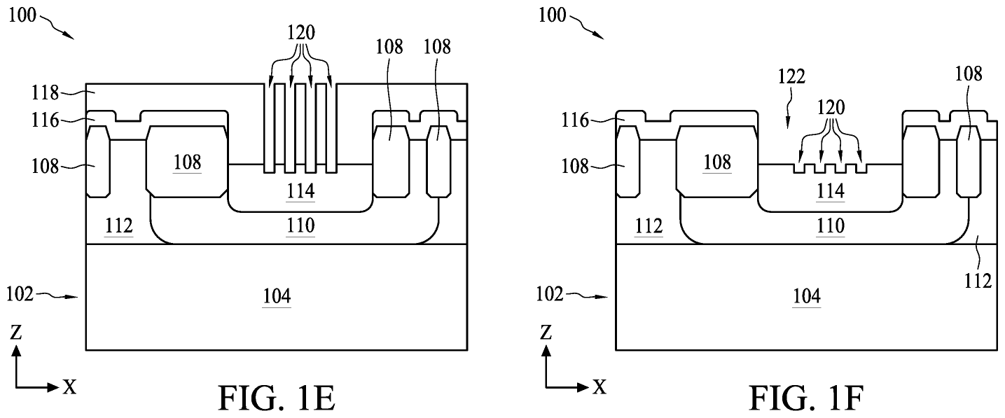

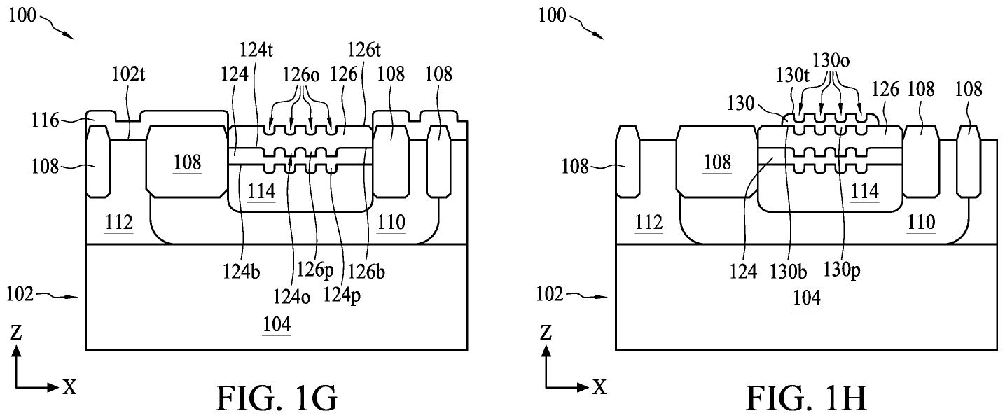

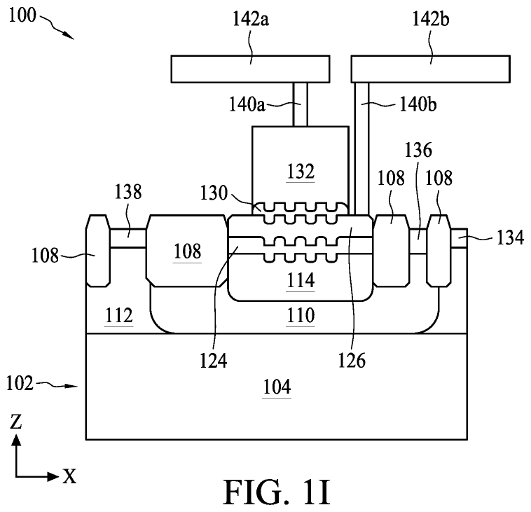

FIGS. 1A-1I illustrate cross-sectional side views of various stages of manufacturing a MOS capacitor structure 100, in accordance with some embodiments. It is understood that additional operations can be provided before, during, and after processes shown by FIGS. 1A-1I, and some of the operations described below can be replaced or eliminated, for additional embodiments of the method. The order of the operations/processes is not limiting and may be interchangeable.

As shown in FIG. 1A, the MOS capacitor structure 100 includes a substrate 102. The substrate 102 can include an elementary semiconductor including silicon or germanium in a single crystal form, a polycrystalline form, or an amorphous form; a compound semiconductor material including at least one of silicon carbide, gallium arsenide, gallium phosphide, indium phosphide, indium arsenide, and indium antimonide; an alloy semiconductor material including at least one of SiGe, GaAsP, AlInAs, AlGaAs, GalnAs, GalnP, and GaInAsP; any other suitable material; or a combination thereof. Furthermore, the substrate 102 may be a semiconductor on insulator, such as silicon on insulator (SOI). The substrate 102 includes a deep well region 104. The deep well region 104 may be a deep n-type well (DNW) region or a deep p-type well (DPW) region. In some embodiments, the MOS capacitor formed from the MOS capacitor structure 100 is an n-type MOS (NMOS) capacitor, and the deep well region 104 includes an n-type dopant, such as Sb, As, P, or any suitable n-type dopant. In some embodiments, the MOS capacitor formed from the MOS capacitor structure 100 is a p-type MOS (PMOS) capacitor, and the deep well region 104 includes a p-type dopant, such as B, Ga, In, BF₂, or any suitable p-type dopant. In some embodiments, the dopant concentration of the deep well region 104 may range from about 100e13 cm⁻³ to about 500e13 cm⁻³. The deep well region 104 may be formed by any suitable process, such as ion implantation or ion diffusion. The substrate 102 further includes a region 106 located over the deep well region 104. The region 106 may be doped in subsequent processes.

As shown in FIG. 1A, the MOS capacitor structure 100 includes one or more isolation regions 108. In some embodiments, the isolation regions 108 are formed by forming trenches in the region 106 and filling the trenches with a dielectric material, such as SiO₂, high-density plasma (HDP) oxide, or other suitable dielectric material. In some embodiments, the height of the isolation regions 108 along the Z direction is substantially greater than the height of the region 106, as shown in FIG. 1A. Alternatively, a planarization process, such as a chemical mechanical polish, is performed after the filling of the trenches with the dielectric material, and the top surfaces of the isolation regions 108 of the top surface of the region 106 are substantially co-planar. The isolation regions 108 may be shallow trench isolation (STI) regions.

In some embodiments, the MOS capacitor structure 100 shown in FIG. 1A is located in a passive device region of a semiconductor device structure, and the semiconductor device structure also includes active device regions (not shown). The active device regions may include active devices, such as transistors, for example field effect transistors (FETs). In some embodiments, the active devices include planar FETs, FinFETs, Horizontal Gate All Around (HGAA) FETs, Vertical Gate All Around (VGAA) FETs, nanosheet FETs, nanowire FETs, forksheet FETs, complementary FETs (CFETs), and other suitable devices. The transistors in the active device regions and the MOS capacitors in the passive devise regions may be formed by the same processes. For example, the deep well region 104, the region 106, and the isolation regions 108 may be also formed in the active device regions of the semiconductor device structure.

As shown in FIG. 1B, a first well region 110 and a second well region 112 are formed in the region 106. The first region 110 may include a conductivity type opposite the conductivity type of the deep well region 104, and the second region 112 may include the same conductivity type as the deep well region 104. For example, the deep well region 104 is a DNW region, the first well region 110 is a p-type well (PW), and the second well region 112 is an n-type well (NW). Alternatively, the deep well region 104 is a DPW region, the first well region 110 is an NW, and the second well region 112 is a PW. The first well region 110 may include an n-type dopant, such as Sb, As, P, or any suitable n-type dopant, or a p-type dopant, such as B, Ga, In, BF₂, or any suitable p-type dopant. The second well region 112 may include an n-type dopant, such as Sb, As, P, or any suitable n-type dopant, or a p-type dopant, such as B, Ga, In, BF₂, or any suitable p-type dopant. In some embodiments, the dopant concentration of the first well region 110 may range from about 100e12 cm⁻³ to about 500e13 cm⁻³, and the dopant concentration of the second well region 112 may range from about 100e12 cm⁻³ to about 100e14 cm⁻³. In some embodiments, the dopant concentration of the second well region 112 may be substantially greater than that of the first well region 110, and the dopant concentration of the deep well region 104 is between the dopant concentrations of the first and second well regions. The first well region 110 and the second well region 112 may be formed by any suitable process, such as ion implantation or ion diffusion. One or more masks (not shown) may be used to form the first and second well regions 110, 112.

In some embodiments, the first and second well regions 110, 112 may be also formed in the active device regions of the semiconductor device structure.

As shown in FIG. 1C, a third well region 114 is formed in the first well region 110. In some embodiments, the third well region 114 has the same conductivity as the first well region 110. For example, the first well region 110 may be a PW region, and the third well region 114 is also a PW region. The third well region 114 may include an n-type dopant, such as Sb, As, P, or any suitable n-type dopant, or a p-type dopant, such as B, Ga, In, BF₂, or any suitable p-type dopant. In some embodiments, the dopant concentration of the third well region 114 may range from about 300e12 cm⁻³ to about 500e13 cm⁻³. In some embodiments, the dopant concentration of the third well region 114 may be substantially greater than that of the first well region 110. The third well region 114 may be formed by any suitable process, such as ion implantation or ion diffusion. In some embodiments, the depth of the third well region 114 is substantially shallower than the depth of the first well region 110. In other words, the height of the third well region 114 is substantially less than the height of the first well region 110. In some embodiments, the height of the third well region 114 is substantially the same as the height of the first well region 110. The third well region 114 may be optional. In some embodiments, the third well region 114 is not formed. During the formation of the third well region 114, a mask (not shown) may be formed over the second well region 112 and the isolation regions 108. The mask may be also formed in the active device regions of the semiconductor device structure. In other words, the third well region 114 may not be formed in the active device regions, and the transistors formed in the active device regions may not include the third well region 114.

As shown in FIG. 1D, a mask 116 is formed over the isolation regions 108 and the second well region 112. The mask 116 may be also formed in the active device regions. The mask 116 may be a hard mask. In some embodiments, the mask 116 includes a dielectric material, such as a nitride. The mask 116 may be formed by first forming a conformal layer on the MOS capacitor structure 100, followed by patterning the conformal layer to form the mask 116. The conformal layer may be formed by a conformal process, such as an atomic layer deposition (ALD) process. The third well region 114 is exposed after the formation of the mask 116.

As shown in FIG. 1E, a photoresist layer 118 is formed on the mask 116 and the third well region 114. One or more openings 120 are formed in the photoresist layer 118, and the openings 120 extend into the third well region 114. In some embodiments, the openings 120 are trenches. The openings 120 may be first formed in the photoresist layer 118 to expose portions of the third well region 114 by a first process, and the exposed portions of the third well region 114 is removed by a second process. After extending the openings 120 into the third well region 114, the photoresist layer 118 is removed. The photoresist layer 118 may be removed by any suitable process, such as an ashing process. The process to remove the photoresist layer 118 does not substantially affect the mask 116 and the third well region 114. In some embodiments, the third well region 114 is not formed, and the openings 120 are formed in the first well region 110. The openings 120 are not formed in the active device regions.

As shown in FIG. 1F, the third well region 114 is recessed, and an opening 122 is formed. In some embodiments, an anisotropic etch process is performed to recess the third well region 114, and the openings 120 are formed in the recessed third well region 114, as shown in FIG. 1F. In other words, the overall height of the third well region 114 is reduced by the recess process, and the openings 120 extend further into the third well region 114. The process to recess the third well region 114 is a selective etch process that does not substantially affect the mask 116. After the recess process, portions of the isolation region 108 surrounding the third well region 114 are exposed. In the embodiment where the third well region 114 is not present, the first well region 110 is recessed, and the openings 120 are formed in the recessed first well region 110.

As shown in FIG. 1G, a first semiconductor layer 124 is formed on the third well region 114. The first semiconductor layer 124 may have a conductivity type opposite the conductivity type of the third well region 114 (or the first well region 110 in the embodiment where the third well region 114 is not present). For example, the third well region 114 is an NW region, and the first semiconductor layer 124 is a p-type semiconductor layer. The first semiconductor layer 124 may include an n-type species, such as Sb, As, P, or any suitable n-type species, or a p-type species, such as B, Ga, In, BF₂, or any suitable p-type species. The concentration of the n-type species or p-type species in the first semiconductor layer 124 may range from about 300c 15 cm⁻³ to about 800e15 cm⁻³. In some embodiments, the concentration of the n-type species or p-type species in the first semiconductor layer 124 may be substantially greater than the dopant concentration of the third well region 114. In some embodiments, the first semiconductor layer 124 includes SiP for an NMOS capacitor or SiGe for a PMOS capacitor. The first semiconductor layer 124 is formed by an epitaxial growth process. The epitaxial growth process grows the first semiconductor layer 124 from the semiconductor material of the third well region 114. In some embodiments, the first semiconductor layer 124 fills the openings 120 (FIG. 1F) in the third well region 114 and is formed on the third well region 114. Due to the openings 120, the first semiconductor layer 124 has a serpentine profile. As shown in FIG. 1G, the first semiconductor layer 124 has a top surface 124t and a bottom surface 124b. The first semiconductor layer 124 further includes one or more protrusions 124p extending downward from the bottom surface 124b towards the third well region 114. One or more openings 1240 are formed in the top surface 124t.

As shown in FIG. 1G, a second semiconductor layer 126 is formed on the first semiconductor layer 124. The second semiconductor layer 126 may have the same conductivity type as that of the first semiconductor layer 124. For example, the first semiconductor layer 124 is a p-type semiconductor layer, and the second semiconductor layer 126 is a p-type semiconductor layer. The second semiconductor layer 126 may include an n-type species, such as Sb, As, P, or any suitable n-type species, or a p-type species, such as B, Ga, In, BF₂, or any suitable p-type species. The concentration of the n-type species or p-type species in the second semiconductor layer 126 may range from about 100e15 cm⁻³ to about 800e15 cm⁻³. In some embodiments, the concentration of the n-type species or p-type species in the second semiconductor layer 126 may be substantially less than the concentration of the n-type species or p-type species in the first semiconductor layer 124. In some embodiments, the second semiconductor layer 126 includes SiP for an NMOS capacitor or SiGe for a PMOS capacitor. Similar to the first semiconductor layer 124, the second semiconductor layer 126 is formed by an epitaxial growth process. The epitaxial growth process grows the second semiconductor layer 126 from the first semiconductor layer 124. In some embodiments, the second semiconductor layer 126 fills the openings 1240 in the first semiconductor layer 124 and is formed on the first semiconductor layer 124. Due to the openings 1240, the second semiconductor layer 126 has a serpentine profile. As shown in FIG. 1G, the second semiconductor layer 126 has a top surface 126t and a bottom surface 126b. The second semiconductor layer 126 further includes one or more protrusions 126p extending downward from the bottom surface 126b towards the first semiconductor layer 124. The protrusions 126p are formed in the openings 1240 of the first semiconductor layer 124. One or more openings 1260 are formed in the top surface 126t of the second semiconductor layer 126. In some embodiments, the top surface 126t is located at a level substantially higher than a level of the top surface 102t of the substrate 102. For example, the vertical distance along the Z direction between the top surface 102t and the top surface 126t may range from about 20 nm to about 50 nm. The openings 1260 formed in the top surface 126t of the second semiconductor layer 126 may have a depth along the Z direction ranging from about 2 nm to about 10 nm.

In some embodiments, the interface between the third well region 114 and the first semiconductor layer 124 is a p-n junction. Because the first semiconductor layer 124 is formed using an epitaxial growth process, the n-type or p-type species in the first semiconductor layer 124 is substantially more stable than n-type or p-type dopants that are introduced into a semiconductor layer by implantation or diffusion. With a semiconductor layer including dopants that are introduced into the semiconductor layer after the formation of the semiconductor layer, the dopants are more likely to diffuse across the p-n junction during subsequent thermal processes. As a result, the depletion region is enlarged, and current leakage paths are created. With the first semiconductor layer 124 being formed using an epitaxial growth process, the n-type or p-type species in the first semiconductor layer 124 generally will not diffuse across the p-n junction during the subsequent thermal processes. As a result, the depletion region remains small, and current leakage is reduced. In some embodiments, the high dopant concentration of the third well region 114, such as greater than about 300e12 cm⁻³, may be used to accommodate the first semiconductor layer 124, which has a high concentration of the n-type or p-type species, such as greater than about 300e15 cm⁻³, and the third well region 114 may provide a gradual change in concentration of dopants/species.

As described above, the high concentration of n-type or p-type species in the first semiconductor layer 124 can help with reduce the size of the depletion region. However, the high concentration of n-type or p-type species can lead to decreased capacitance. Thus, in some embodiments, the concentration of n-type or p-type species in the second semiconductor layer 126 is substantially less than that in the first semiconductor layer 124. For example, the concentration of n-type or p-type species in the first semiconductor layer 124 is about 1.5 times to about 5 times, such as about 2 times to about 3 times, the concentration of n-type or p-type species in the second semiconductor layer 126. The second semiconductor layer 126 having less concentration of n-type or p-type species can lead to increased capacitance. Furthermore, in some embodiments, the second semiconductor layer 126 is substantially thicker than the first semiconductor layer 124. For example, the first semiconductor layer 124 has a first thickness along the Z direction, and the second semiconductor layer 126 has a second thickness along the Z direction substantially greater than the first thickness. The small first thickness of the first semiconductor layer 124 can lead to a small depletion region. However, if the first thickness is too small, the quality of the p-n junction may be negatively affected. Thus, in some embodiments, the first thickness is about 20 percent to about 50 percent of the second thickness. If the first thickness is less than about 20 percent of the second thickness, the quality of the p-n junction is negatively affected. On the other hand, if the first thickness is greater than about 50 percent of the second thickness, the capacitance of the MOS capacitor is reduced.

As described above, the mask 116 is formed in the active device regions. Thus, the first and second semiconductor layers 124, 126 are not formed in the active device regions. In other words, the transistors formed in the active device regions do not include the first and second semiconductor layers 124, 126.

As shown in FIG. 1H, the mask 116 is removed, and a dielectric layer 130 is formed on the second semiconductor layer 126. In some embodiments, the dielectric layer 130 fills the openings 1260 in the second semiconductor layer 126 and is formed on the second semiconductor layer 126. Due to the openings 1260, the dielectric layer 130 has a serpentine profile. As shown in FIG. 1H, the dielectric layer 130 has a top surface 130t and a bottom surface 130b. The dielectric layer 130 further includes one or more protrusions 130p extending downward from the bottom surface 130b towards the second semiconductor layer 126. The protrusions 130p are formed in the openings 1260 of the second semiconductor layer 126. One or more openings 1300 are formed in the top surface 130t of the dielectric layer 130. In some embodiments, the dielectric layer 130 is an oxide layer, such as a silicon oxide layer. The dielectric layer 130 is also formed in the active device regions and may be the gate oxide (GOX) layer for the transistors formed in the active device regions. The dielectric layer 130 may be formed by first forming a blanket layer on the semiconductor device structure, which includes the MOS capacitor structure 100 in the passive device region and other structures in the active device regions. The blanket layer may be formed by any suitable process, such as thermal growth, chemical vapor deposition (CVD), plasma enhanced chemical vapor deposition (PECVD), or atomic layer deposition (ALD). The blanket layer is then patterned to form the dielectric layer 130. In the active device regions, portions of the blanket layer formed on regions other than the channel regions, i.e., the first well region 110 in the active device regions, may be removed. The dielectric layer 130 located in the passive device region has a serpentine profile and includes one or more openings 1300, as shown in FIG. 1H. The dielectric layer 130, or the gate oxide layer, located in the active device regions does not have the serpentine profile. In other words, the top surface and bottom surface of the dielectric layer 130 located in the active device regions may be substantially flat, while the top surface of the dielectric layer 130 located in the passive device region has recesses, and the bottom surface of the dielectric layer 130 located in the passive device region has protrusions, as shown in FIG. 1H. The serpentine profile of the dielectric layer 130 located in the passive device region has an increased surface area compared to the dielectric layer 130 located in the active device region, and the increased surface area increases the capacitance.

In some embodiments, the width of the dielectric layer 130 along the X direction is substantially smaller than the width of the second semiconductor layer 126. The exposed portion of the second semiconductor layer 126 may be used to receive a conductive feature 140b (FIG. 1I).

As shown in FIG. 1I, a gate structure 132 is formed on the dielectric layer 130, and doped regions 134, 136, 138 are formed. In some embodiments, the gate structure 132 includes a gate dielectric layer, one or more work function layers, and a gate electrode layer. In some embodiments, the gate dielectric layer includes one or more layers of a dielectric material, such as silicon oxide, silicon nitride, or high-K dielectric material, other suitable dielectric material, and/or combinations thereof. Examples of high-K dielectric material include HfO₂, HfSiO, HfSiON, HfTaO, HfTIO, HfZrO, zirconium oxide, aluminum oxide, titanium oxide, hafnium dioxide-alumina (HfO₂—Al₂O₃) alloy, other suitable high-K dielectric materials, and/or combinations thereof. The gate dielectric layer may be formed by CVD, ALD or any suitable deposition technique. The work function layer may include a metallic material, such as platinum (Pt), palladium (Pd), tantalum (Ta), ytterbium (Yb), aluminum (Al), silver (Ag), titanium (Ti), ruthenium (Ru), molybdenum (Mo), chromium (Cr), tungsten (W), copper (Cu), or similar material. The gate electrode layer may include one or more layers of electrically conductive material, such as polysilicon, aluminum, copper, titanium, tantalum, tungsten, cobalt, molybdenum, tantalum nitride, nickel silicide, cobalt silicide, TIN, WN, TiAl, TiAlN, TaCN, TaC, TaSiN, metal alloys, other suitable materials, and/or any combinations thereof. The gate electrode layer may be formed by CVD, ALD, electro-plating, or other suitable deposition technique. In some embodiments, as shown in FIG. 1I, the width of the gate structure 132 is substantially the same as the width of the dielectric layer 130.

In some embodiments, an interlayer dielectric (ILD) layer (not shown) is formed over the semiconductor device structure, which includes the active device regions and the passive device regions. The materials for the ILD layer may include compounds including Si, O, C, and/or H, such as silicon oxide, SiCOH, or SiOC. Organic materials, such as polymers, may also be used for the ILD layer. The ILD layer may be deposited by a PECVD process or other suitable deposition technique. In some embodiments, after formation of the ILD layer, the semiconductor device structure may be subject to a thermal process to cure the ILD layer. In some embodiments, a contact etch stop layer (CESL) (not shown) may be formed on the semiconductor device structure, and the ILD layer is formed on the CESL. The CESL may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique.

The gate structure 132 is formed by a gate-first process or a gate-last process. The gate structure 132 is also formed in the active device regions to function as a gate of a transistor. The gate electrode layer of the gate structure 132 formed in the passive device region functions as the top electrode of the MOS capacitor, while the first and second semiconductor layers 124, 126 function as the bottom electrode of the MOS capacitor. The dielectric layer 130 (and the gate dielectric layer in some embodiments) functions as the insulator of the MOS capacitor.

The doped regions 134, 136, 138 may be formed prior to the formation of the CESL and the ILD layer. The doped regions 134, 136, 138 may be formed by an implantation process. As shown in FIG. 1I, in some embodiments, the doped regions 134, 138 are formed in the second well region 112 and include the same type of dopant as the second well region 112. The doped region 136 is formed in the first well region 110 and includes the same type of dopant as the first well region 110. The dopant concentration of the doped regions 134, 138 may be substantially greater than the dopant concentration of the second well region 112, and the dopant concentration of the doped region 136 may be substantially greater than the dopant concentration of the first well region 110. The doped regions 134, 136, 138 may be utilized for electrical contacts, such as ground contact. In some embodiments, one or more masks (not shown) are used to formed the doped regions 134, 136, 138 in the passive device region, and the same masks may be used to form the source/drain regions (not shown) in the active device regions. In other words, the doped regions 134, 136, 138 may be formed by the same processes as the source/drain regions.

As shown in FIG. 1I, the MOS capacitor structure 100 may further includes conductive features 140a, 140b, 142a, 142b. The conductive features 140a, 140b, 142a, 142b may each include an electrically conductive material, such as Ru, Mo, Co, Ni. W, Ti, Ta, Cu, Al, TiN or TaN. The conductive features 140a, 140b, 142a, 142b may be formed by any suitable method, such as electro-chemical plating (ECP), or PVD. The conductive features 140a, 140b, 142a, 142b may be formed in the ILD layer and/or an intermetal dielectric (IMD) layer. In some embodiments, the conductive features 140a, 142a provide a current path to the gate structure 132, or the top electrode of the MOS capacitor, and the conductive features 140b, 142b provide a current path to the second semiconductor layer 126, or the bottom electrode of the MOS capacitor.

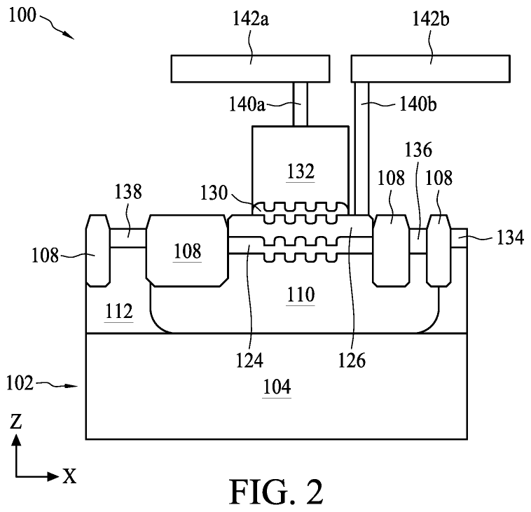

FIGS. 2, 3A, 3B, 4A-4D illustrate cross-sectional side views of the MOS capacitor structure, in accordance with alternative embodiments. As shown in FIG. 2, in some embodiments, the third well region 114 is not formed, and the first semiconductor layer 124 having the serpentine profile is in contact with the first well region 110. Instead of forming the one or more openings 120 in the third well region 114, one or more openings are formed in the first well region 110, and the first semiconductor layer 124 is epitaxially grown from the first well region 110.

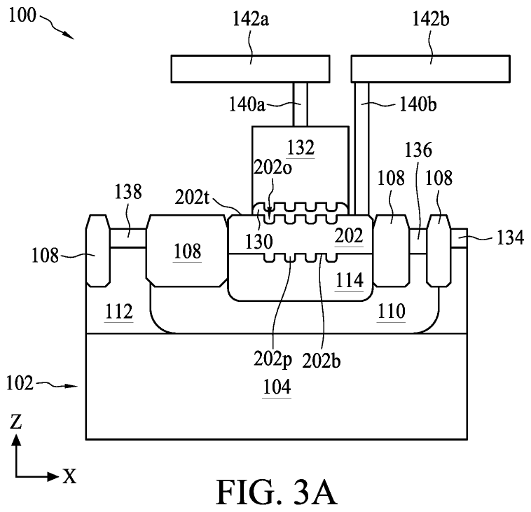

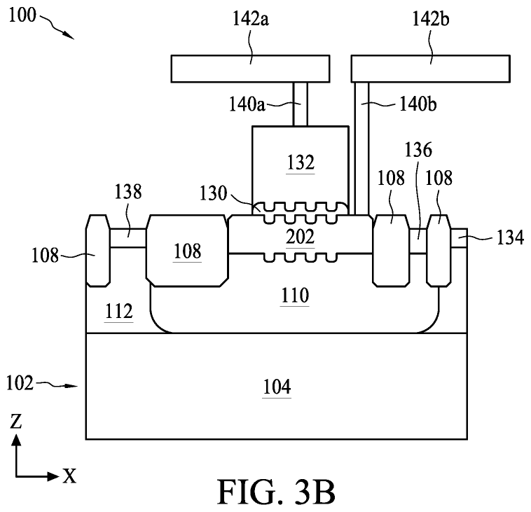

In some embodiments, a single semiconductor layer 202 having gradient concentration of n-type or p-type species is formed instead of the first and second semiconductor layers 124, 126, as shown in FIGS. 3A and 3B. As shown in FIG. 3A, the semiconductor layer 202 is formed in the openings 120 (FIG. 1F) and on the third well region 114, and the dielectric layer 130 is formed on the semiconductor layer 202. Similar to the first and second semiconductor layers 124, 126, one or more openings are formed in the top surface of the semiconductor layer 202, and the dielectric layer 130 is formed in the openings and on the semiconductor layer 202. The semiconductor layer 202 has a gradient concentration of n-type or p-type species. For example, the concentration of the n-type or p-type species may decrease in a direction from the bottom surface of the semiconductor layer 202 to the top surface of the semiconductor layer 202. Thus, the portion of the semiconductor layer 202 adjacent the third well region 114 has a high concentration of n-type or p-type species, which leads to small depletion region. The portion of the semiconductor layer 202 adjacent the dielectric layer 130 has a low concentration of n-type or p-type species, which leads to increased capacitance. The semiconductor layer 202 may include the same materials as the first and second semiconductor layers 124, 126, and the concentration of n-type or p-type species ranges from about 100e15 cm⁻³ to about 800e15 cm⁻³. For example, the portion of the semiconductor layer 202 adjacent the third well region 114 may have a concentration of n-type or p-type species that is about 1.5 times to about 5 times, such as from about 2 times to about 3 times, the concentration of n-type or p-type species of the portion of the semiconductor layer 202 adjacent the dielectric layer 130.

In some embodiments, as shown in FIG. 3A, the semiconductor layer 202 has a serpentine profile. The semiconductor layer 202 has a top surface 202t and a bottom surface 202b. The semiconductor layer 202 further includes one or more protrusions 202p extending downward from the bottom surface 202b towards the third well region 114. One or more openings 2020 are formed in the top surface 202t.

As shown in FIG. 3B, in some embodiments, the third well region 114 is not formed, and the semiconductor layer 202 having the serpentine profile is in contact with the first well region 110. Instead of forming the one or more openings 120 in the third well region 114, one or more openings are formed in the first well region 110, and the semiconductor layer 202 is epitaxially grown from the first well region 110.

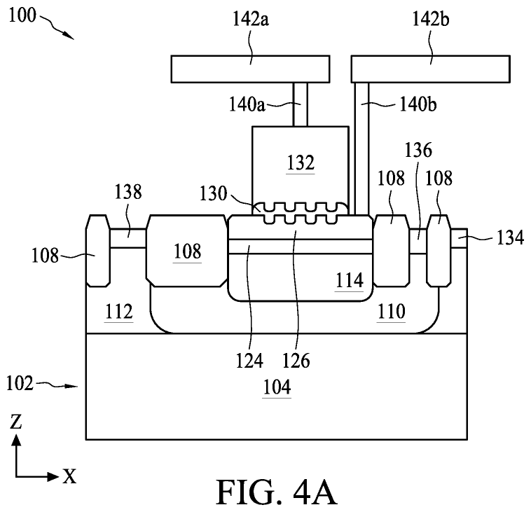

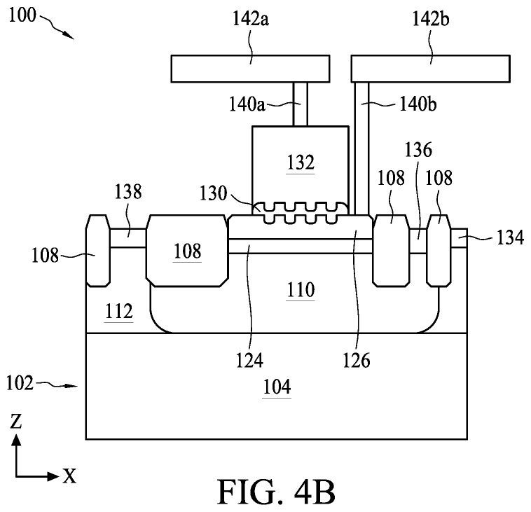

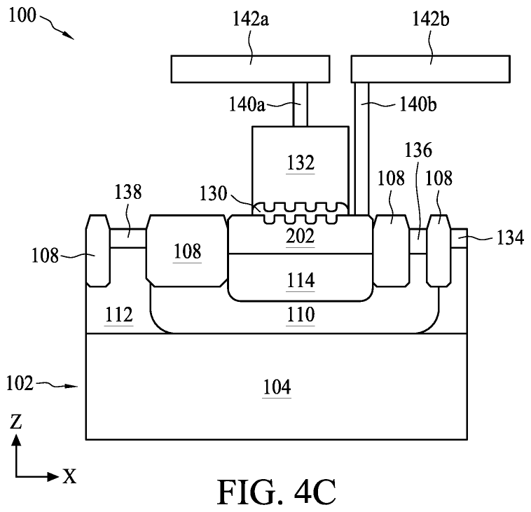

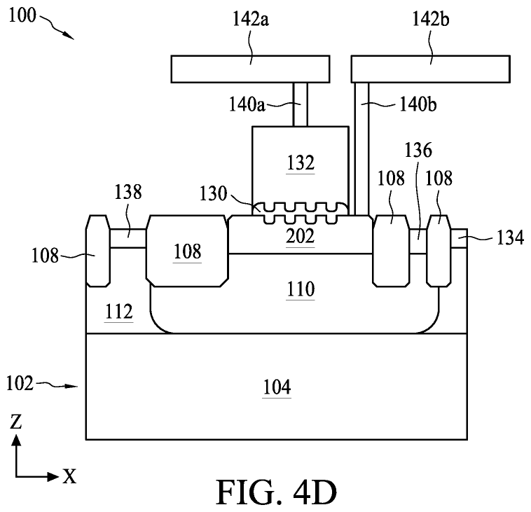

In some embodiments, the surface area of the dielectric layer 130 is increased by forming one or more openings in the second semiconductor layer 126 and then forming the dielectric layer 130 in the openings in the second semiconductor layer 126, as shown in FIGS. 4A-4D. The openings 1260 shown in FIG. 1G is the result of the openings 120 (FIG. 1F) formed in the third well region 114 (or the first well region 110). Thus, the depth of the openings 1260 is not controlled. By forming the one or more openings directly in the second semiconductor layer 126, the depth of the openings can be controlled. In some embodiments, after the processes performed in FIG. 1D, the third well region 114 (or the first well region 110 if the third well region 114 is not formed) is recessed without forming the one or more openings 120. The first semiconductor layer 124 is epitaxially grown from a substantially flat top surface of the third well region 114, and the first semiconductor layer 124 does not have a serpentine profile, as shown in FIG. 4A. The second semiconductor layer 126 is epitaxially grown from a substantially flat top surface of the first semiconductor layer 124, and the second semiconductor layer 126 has a substantially flat top surface. Next, the processes performed in FIG. 1E may be performed on the second semiconductor layer 126, and one or more openings are formed in the second semiconductor 126. The etch process to form the one or more openings in the second semiconductor layer 126 may be controlled to form the one or more openings having a predetermined depth.

In some embodiments, as shown in FIG. 4B, the third well region 114 is not formed. The first well region 110 is recessed, and the first semiconductor layer 124 is formed on the substantially flat top surface of the first well region 110. In some embodiments, as shown in FIG. 4C, the semiconductor layer 202 is formed on the substantially flat top surface of the third well region 114, and the one or more openings are formed in the semiconductor layer 202. Similarly, the process to form the one or more openings in the semiconductor layer 202 is controlled, so the one or more openings have a predetermined depth. In some embodiments, as shown in FIG. 4D, the semiconductor layer 202 is formed on the substantially flat top surface of the first well region 110.

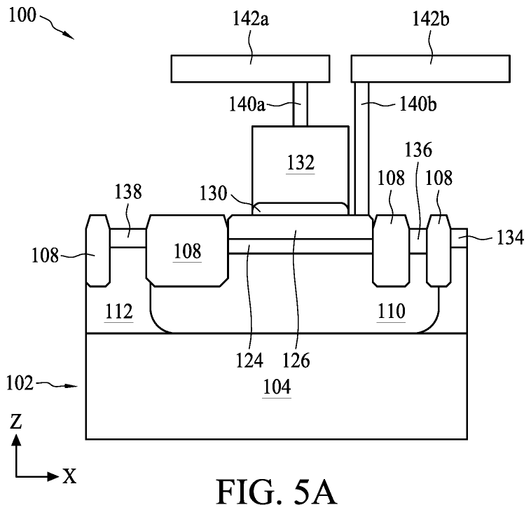

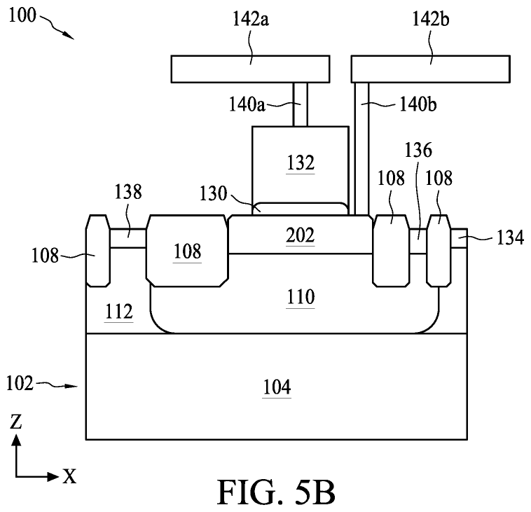

In some embodiments, the first and second semiconductor layers 124, 126, the semiconductor layer 202, and the dielectric layer 130 do not have the serpentine profile, and the first and second semiconductor layers 124, 126, the semiconductor layer 202, and the dielectric layer 130 each has a flat profile, as shown in FIGS. 5A and 5B. As described above, as shown in FIG. 5A, the first and second semiconductor layers 124, 126 are formed by an epitaxial growth process, and the species in the first and second semiconductor layers 124, 126 is more stable than dopants in a semiconductor layer formed by implantation or diffusion. The openings are not formed in the second semiconductor layer 126 (FIG. 4A), and the dielectric layer 130 is deposited on a substantially flat top surface of the second semiconductor layer 126. Similarly, as shown in FIG. 5B, the semiconductor layer 202 is formed by an epitaxial growth process, and the species in the semiconductor layer 202 is more stable than dopants in a semiconductor layer formed by implantation or diffusion. The openings are not formed in the semiconductor layer 202 (FIG. 4C), and the dielectric layer 130 is deposited on a substantially flat top surface of the semiconductor layer 206. As a result of having the first and second semiconductor layers 124, 126 or the semiconductor layer 202 formed by an epitaxial growth process, the size of the depletion region is reduced, and current leakage is prevented.

In some embodiments, similar to the processes described in FIGS. 1A to 1I, the third well region 114, the first semiconductor layer 124 (with a flat profile as shown FIGS. 4A, 4B, 5A, or a serpentine profile as shown in FIGS. 1I, 2), the second semiconductor layer 126 (with a flat bottom surface as shown in FIGS. 4A, 4B, a flat profile as shown in FIG. 5A, or with a serpentine profile as shown in FIGS. 1I, 2), and the semiconductor layer 202 (with a flat bottom surface as shown in FIGS. 4C, 4D, a flat profile as shown in FIG. 5B, or with a serpentine profile as shown in FIGS. 3A, 3B) described in FIGS. 2, 3A, 3B, 4A-4D, 5A, and 5B may not be formed in the active device region. Thus, the transistors, such as planar transistors, located in the active device region may not include the third well region 114, the first semiconductor layer 124 (with a flat profile or a serpentine profile), the second semiconductor layer 126 (with a flat bottom surface or with a serpentine profile), and the semiconductor layer 202 (with a flat bottom surface or with a serpentine profile). In some embodiments, a transistor located in the active device region includes the first well region 110, which may be the channel region, the dielectric layer 130 having a flat profile, which may be the GOX, the gate structure 132, and the source/drain regions located on opposite sides of the gate structure 132. In contrast, the MOS capacitor structure 100 in the passive device region includes at least one capacitor having a bottom electrode, which may be the first semiconductor layer 124, the second semiconductor layer 126, the semiconductor layer 202, or combinations thereof, an insulator, which may be the dielectric layer 130, and a top electrode, which may be the gate electrode layer of the gate structure 132.

Embodiments of the present disclosure provide a MOS capacitor structure 100. In some embodiments, the MOS capacitor structure 100 includes one or more semiconductor layers, such as the first and second semiconductor layers 124, 126, or the semiconductor layer 202, that are formed by an epitaxial growth process. In some embodiments, a dielectric layer, such as the dielectric layer 130, formed on the one or more semiconductor layer has a serpentine profile. Some embodiments may achieve advantages. For example, the epitaxially grown one or more semiconductor layers are more stable compared to the doped semiconductor layers formed by implantation or diffusion, and the n-type or p-type species in the one or more semiconductor layers does not diffuse into adjacent regions during thermal processes. As a result, the size of the depletion region is reduced. In addition, the serpentine profile of the dielectric layer formed on the one or more semiconductor layers has an increased surface area compared to a layer having a flat profile. As a result, capacitance is increased.

An embodiment is a capacitor structure. The structure includes a first well region, a first semiconductor layer disposed over the first well region, a second semiconductor layer disposed on the first semiconductor layer, and a dielectric layer disposed on the second semiconductor layer. The dielectric layer has a top surface, a bottom surface, one or more protrusions extending towards the second semiconductor layer, and one or more openings in the top surface. The structure further includes a gate structure disposed on the dielectric layer.

Another embodiment is a capacitor structure. The structure includes a first well region and a semiconductor layer disposed over the first well region. The semiconductor layer has a gradient concentration of n-type or p-type species that decreases in a direction from a bottom surface of the semiconductor layer to a top surface of the semiconductor layer, and one or more openings are formed in the top surface of the semiconductor layer. The structure further includes a dielectric layer disposed on the semiconductor layer and in the one or more openings and a gate structure disposed on the dielectric layer.

A further embodiment is a method. The method includes forming a first isolation region and a second isolation region in a substrate, forming a first well region between the first and second isolation regions, forming a second well region in the first well region, forming one or more openings in the second well region, and recessing the second well region. The one or more openings are extended into the recessed second well region. The method further includes forming a first semiconductor layer on the second well region and in the one or more openings, the first semiconductor layer is formed by an epitaxial growth process, and the first semiconductor layer has a serpentine profile. The method further includes depositing a dielectric layer over the first semiconductor layer, and the dielectric layer has a serpentine profile.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A capacitor structure, comprising:
a first well region;
a first semiconductor layer disposed over the first well region;
a second semiconductor layer disposed on the first semiconductor layer;
a dielectric layer disposed on the second semiconductor layer, wherein the dielectric layer has a top surface, a bottom surface, one or more protrusions extending towards the second semiconductor layer, and one or more openings in the top surface; and
a gate structure disposed on the dielectric layer.

2. The capacitor structure of claim 1, further comprising a second well region disposed in the first well region.

3. The capacitor structure of claim 2, wherein the first well region and the second well region comprise dopants of a same conductivity type.

4. The capacitor structure of claim 2, wherein a dopant concentration of the second well region is substantially greater than a dopant concentration of the first well region.

5. The capacitor structure of claim 1, wherein the first semiconductor layer comprises a species of a first conductivity type, and the first well region comprises a dopant of a second conductivity type opposite the first conductivity type.

6. The capacitor structure of claim 5, wherein the first and second semiconductor layers comprise species of a same conductivity type.

7. The capacitor structure of claim 1, wherein the first and second semiconductor layers are formed by an epitaxial growth process.

8. The capacitor structure of claim 1, wherein the first semiconductor layer and the second semiconductor layer each has a serpentine profile.

9. A capacitor structure, comprising:
a first well region;
a semiconductor layer disposed over the first well region, wherein the semiconductor layer has a gradient concentration of n-type or p-type species that decreases in a direction from a bottom surface of the semiconductor layer to a top surface of the semiconductor layer, and one or more openings are formed in the top surface of the semiconductor layer;
a dielectric layer disposed on the semiconductor layer and in the one or more openings; and
a gate structure disposed on the dielectric layer.

10. The capacitor structure of claim 9, wherein the semiconductor layer further comprises one or more protrusions extending towards the first well region.

11. The capacitor structure of claim 9, wherein the bottom surface of the semiconductor layer is substantially flat.

12. The capacitor structure of claim 9, further comprising a second well region disposed in the first well region, wherein the first well region and the second well region comprise dopants of a same conductivity type.

13. The capacitor structure of claim 9, wherein the semiconductor layer comprises a species of a first conductivity type, and the first well region comprises dopants of a second conductivity type opposite the first conductivity type.

14. The capacitor structure of claim 13, further comprising a deep well region, wherein the deep well region comprises dopants of the first conductivity type.

15. The capacitor structure of claim 14, further comprising a third well region surrounding the first well region, wherein the third well region comprises dopants of the first conductivity type.

16. A method, comprising:
forming a first isolation region and a second isolation region in a substrate;
forming a first well region between the first and second isolation regions;
forming a second well region in the first well region;
forming one or more openings in the second well region;
recessing the second well region, wherein the one or more openings are extended into the recessed second well region;
forming a first semiconductor layer on the second well region and in the one or more openings, wherein the first semiconductor layer is formed by an epitaxial growth process, and the first semiconductor layer has a serpentine profile; and
depositing a dielectric layer over the first semiconductor layer, wherein the dielectric layer has a serpentine profile.

17. The method of claim 16, further comprising forming a second semiconductor layer on the first semiconductor layer, wherein the second semiconductor layer is formed by an epitaxial growth process, and the second semiconductor layer has a serpentine profile.

18. The method of claim 16, wherein the first well region and the second well region are formed by an implantation process or a diffusion process.

19. The method of claim 17, further comprising forming a gate structure on the dielectric layer.

20. The method of claim 19, further comprising forming a first conductive feature electrically connected to the gate structure and forming a second conductive feature electrically connected to the second semiconductor layer.
